(19) United States
(12) Patent Application Publication
(10) Pub. No.: US 2004/0058271 A1
(43) Pub. Date: Mar. 25, 2004

(54) Pattern formation material, water-soluble material and pattern formation method

(75) Inventors: Masayuki Endo, Osaka (JP); Masaru Sasago, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/641,042

(22) Filed: Aug. 15, 2003

(30) Foreign Application Priority Data
Sep. 25, 2002 (JP) 2002-278492

(51) Int. Cl. G03F 7/00

(52) U.S. Cl. 430/270.1; 430/913; 430/905; 430/911; 430/311; 430/945; 430/942

(57) ABSTRACT

The pattern formation material of this invention is composed of a chemically amplified resist material. The chemically amplified resist material includes a polymer whose solubility in a developer is changed owing to a function of an acid; an acid generator that generates an acid through irradiation with an energy beam; and a compound that absorbs outgassing induced from the polymer or the acid generator.

### BACKGROUND OF THE INVENTION

The present invention relates to a pattern formation material, a water-soluble material and a pattern formation method for use in fabrication process for semiconductor devices.

In accordance with the increased degree of integration of semiconductor integrated circuits and downsizing of semiconductor devices, there are increasing demands for further rapid development of lithography technique. Currently, pattern formation is carried out through photolithography using exposing light of a mercury lamp, KrF excimer laser, ArF excimer laser or the like.

However, in order to form a fine pattern with a pattern width of a 0.1 μm or less, and more particularly, of 70 nm or less, use of exposing light of a further shorter wavelength, such as vacuum UV like F₂ laser (of a wavelength of a 157 nm band) or extreme UV (of a wavelength of a 1 nm through 30 nm band) as well as use of an electron beam (EB) employing EB projection exposure or the like is being studied.

As described by T. Watanabe et al., in “Photoinduced outgassing from the resist for extreme ultraviolet lithography by the analysis of mass spectroscopy” (J. Vac. Sci. Tech. B, vol. 19, 736 (2001), issued in May 2001), in the case where vacuum UV, extreme UV or EB is used as the exposing light, it is necessary to reduce outgassing induced from a resist film subjected to pattern exposure. When outgassing is induced from a resist film, the outgassing adheres onto a mirror or a mask of the exposure system, so as to disadvantageously lower the luminance of the exposing light used for irradiating the resist film.

Now, a conventional pattern formation method in which a resist film made from a chemically amplified resist material is selectively irradiated with extreme UV for pattern exposure will be described with reference to FIGS. 5A through 5D.

First, a chemically amplified resist material having the following composition is prepared:

Polymer: poly((t-butyl methacrylate)—(mevalonic lactone methacrylate))

(wherein t-butyl methacrylate: mevalonic lactone methacrylate=50 mol %:50 mol %) . . . 2 g

Acid generator: triphenylsulfonium triflate . . . 0.08 g

Solvent: propylene glycol monomethyl ether acetate . . . 20 g

Next, as shown in FIG. 5A, the aforementioned chemically amplified resist material is applied on a semiconductor substrate 1 by spin coating, so as to form a resist film 2 with a thickness of 0.2 μm.

Then, as shown in FIG. 5B, pattern exposure is carried out by irradiating the resist film 2 with extreme UV 3 of a wavelength of 13.5 nm in vacuum through a reflection mask not shown.

Thereafter, as shown in FIG. 5C, the resist film 2 is subjected to post-bake with a hot plate at a temperature of 100° C. for 60 seconds. Thus, an exposed portion 2a of the resist film 2 becomes soluble in an alkaline developer owing to the function of an acid generated from the acid generator while an unexposed portion 2b of the resist film 2 remains to be insoluble in an alkaline developer because no acid is generated from the acid generator therein.

Next, as shown in FIG. 5D, the resist film 2 is developed with a 2.38 wt % tetramethylammonium hydroxide developer (alkaline developer), so as to form a resist pattern 4 with a line width of 0.07 μm.

As shown in FIG. 5D, however, the resultant resist pattern 4 is disadvantageously degraded in its cross-sectional shape. It seems that the resist pattern 4 is in such a defective shape because outgassing that is induced from the resist film during the pattern exposure adheres onto a mirror or a mask of the exposure optical system. Specifically, when the outgassing adheres onto the mirror or the mask of the exposure system, the luminance of exposing light used for irradiating the resist film is lowered. As a result, there arise a problem of degradation of the shape of the resist pattern and a problem of lowering of the throughput.

### SUMMARY OF THE INVENTION

In consideration of the aforementioned conventional problems, an object of the invention is improving the shape of a resist pattern and improving the throughput by reducing outgassing induced from a resist film subjected to pattern exposure.

In order to achieve the object, the pattern formation material of this invention is composed of a chemically amplified resist material that includes a polymer whose solubility in a developer is changed owing to a function of an acid; an acid generator that generates an acid through irradiation with an energy beam; and a compound that absorbs outgassing induced from the polymer or the acid generator.

In the pattern formation material of this invention, since the chemically amplified resist material includes the compound for absorbing the outgassing induced from the polymer or the acid generator, the outgassing induced from a resist film during pattern exposure of the resist film is absorbed by the compound that is included in the chemically amplified resist material for absorbing the outgassing and hence is minimally released in an exposure system. Therefore, luminance of exposing light used for irradiating the resist film can be prevented from lowering because of the outgassing adhered onto a mask or a mirror. As a result, degradation of the shape of a resist pattern and lowering of the throughput can be avoided.

In the pattern formation material of this invention, the compound is preferably activated carbon.

Thus, the compound of the activated carbon can efficiently absorb the outgassing.

In this case, a weight ratio of the activated carbon to the polymer is preferably not less than 0.1% and not more than 30%.

Thus, the outgassing can be definitely and efficiently absorbed.

Also, the activated carbon is preferably particulate activated carbon.

Thus, the outgassing can be more efficiently absorbed.

In this case, the particulate activated carbon can be crushed carbon, granular carbon, mold carbon (cylindrical carbon) or particulate carbon.

The water-soluble material of this invention is used for forming a water-soluble film on a resist film that is made from a chemically amplified resist material including a polymer whose solubility in a developer is changed owing to a function of an acid and an acid generator that generates an acid through irradiation with an energy beam, and the water-soluble material includes a water-soluble polymer; and a compound that absorbs outgassing induced from the resist film.

Since the water-soluble material of this invention includes the compound for absorbing the outgassing induced from the resist film, the outgassing induced from the resist film during the pattern exposure of the resist film is absorbed by the compound that is included in the water-soluble film for absorbing the outgassing and hence is minimally released in the exposure system. Therefore, the luminance of the exposing light used for irradiating the resist film can be prevented from lowering because of the outgassing adhered onto a mask or a mirror. As a result, the degradation of the shape of a resist pattern and lowering of the throughput can be avoided.

In the water-soluble material of this invention, the water-soluble polymer can be one or two polymers selected from the group consisting of polyacrylic acid, polystyrene sulfonic acid, hydroxyethylcellulose, polyisoprene sulfonic acid, polyvinyl pyrrolidone and pullulan.

In the water-soluble material of this invention, the compound is preferably activated carbon.

Thus, the compound of the activated carbon can efficiently absorb the outgassing.

In this case, the activated carbon is preferably particulate activated carbon.

Thus, the outgassing can be more efficiently absorbed.

In this case, the particulate activated carbon can be crushed carbon, granular carbon, mold carbon (cylindrical carbon) or particulate carbon.

The first pattern formation method of this invention includes the steps of forming a resist film made from a chemically amplified resist material including a polymer whose solubility in a developer is changed owing to a function of an acid, an acid generator that generates an acid through irradiation with an energy beam and a compound that absorbs outgassing induced from the polymer or the acid generator; performing pattern exposure by selectively irradiating the resist film with an energy beam; and forming a resist pattern by developing the resist film with a developer after the pattern exposure.

In the first pattern formation method of this invention, since the chemically amplified resist material includes the compound for absorbing the outgassing induced from the polymer or the acid generator, the outgassing induced from the resist film during the pattern exposure of the resist film is absorbed by the compound that is included in the chemically amplified resist material for absorbing the outgassing and hence is minimally released in an exposure system. Therefore, the luminance of the exposing light used for irradiating the resist film can be prevented from lowering because of the outgassing adhered onto a mask or a mirror. As a result, the degradation of the shape of the resist pattern and the lowering of the throughput can be avoided.

The second pattern formation method of this invention includes the steps of forming a resist film made from a chemically amplified resist material including a polymer whose solubility in a developer is changed owing to a function of an acid and an acid generator that generates an acid through irradiation with an energy beam; forming, on the resist film, a water-soluble film made from a water-soluble material including a water-soluble polymer and a compound that absorbs outgassing induced from the resist film; performing pattern exposure by selectively irradiating the water-soluble film and the resist film with an energy beam; and removing the water-soluble film and forming a resist pattern made from the resist film by developing the water-soluble film and the resist film with a developer after the pattern exposure.

In the second pattern formation method of this invention, since the water-soluble film formed on the resist film includes the compound for absorbing the outgassing induced from the resist film, the outgassing induced from the resist film during the pattern exposure is absorbed by the compound that is included in the water-soluble film for absorbing the outgassing and hence is minimally released in an exposure system. Therefore, the luminance of the exposing light used for irradiating the resist film can be prevented from lowering because of the outgassing adhered onto a mask or a mirror. As a result, the degradation of the shape of the resist pattern and the lowering of the throughput can be avoided. Also, the water-soluble film made from the water-soluble material does not mix with a resist material and can be easily removed with a developer.

The third pattern formation method of this invention includes the steps of forming a resist film made from a chemically amplified resist material including a polymer whose solubility in a developer is changed owing to a function of an acid and an acid generator that generates an acid through irradiation with an energy beam; forming, on the resist film, a water-soluble film made from a water-soluble material including a water-soluble polymer and a compound that absorbs outgassing induced from the resist film; performing pattern exposure by selectively irradiating the water-soluble film and the resist film with an energy beam; removing the water-soluble film after the pattern exposure; and forming a resist pattern by developing the resist film with a developer after the pattern exposure.

In the third pattern formation method of this invention, since the water-soluble film formed on the resist film includes the compound for absorbing the outgassing induced from the resist film, the outgassing induced from the resist film during the pattern exposure is absorbed by the compound that is included in the water-soluble film for absorbing the outgassing and hence is minimally released in an exposure system. Therefore, the luminance of the exposing light used for irradiating the resist film can be prevented from lowering because of the outgassing adhered onto a mask or a mirror. As a result, the degradation of the shape of the resist pattern and the lowering of the throughput can be avoided. Also, the water-soluble film made from the water-soluble material does not mix with a resist material and can be easily removed with water.

In the second or third pattern formation method, the water-soluble polymer can be one or two polymers selected from the group consisting of polyacrylic acid, polystyrene sulfonic acid, hydroxyethylcellulose, polyisoprene sulfonic acid, polyvinyl pyrrolidone and pullulan.

In any of the first through third pattern formation methods, the energy beam can be F₂ laser, extreme UV or an electron beam.

In any of the first through third pattern formation methods, the compound is preferably activated carbon.

Thus, the compound of the activated carbon can efficiently absorb the outgassing.

In this case, a weight ratio of the activated carbon to the polymer is preferably not less than 0.1% and not more than 30%.

Thus, the outgassing can be definitely and efficiently absorbed.

Also, the activated carbon is preferably particulate activated carbon.

Thus, the outgassing can be more efficiently absorbed.

In this case, the particulate activated carbon can be crushed carbon, granular carbon, mold carbon (cylindrical carbon) or particulate carbon.

### BRIEF DESCRIPTION OF THE DRAWINGS

FIGS. 1A, 1B, 1C and 1D are cross-sectional views for showing procedures in a pattern formation method according to Embodiment 1 of the invention;

FIGS. 2A, 2B, 2C, 2D and 2E are cross-sectional views for showing procedures in a pattern formation method according to Embodiment 2 of the invention;

FIGS. 3A, 3B and 3C are cross-sectional views for showing procedures in a pattern formation method according to Embodiment 3 of the invention;

FIGS. 4A, 4B and 4C are cross-sectional views for showing other procedures in the pattern formation method of Embodiment 3; and

FIGS. 5A, 5B, 5C and 5D are cross-sectional views for showing procedures in a conventional pattern formation method.

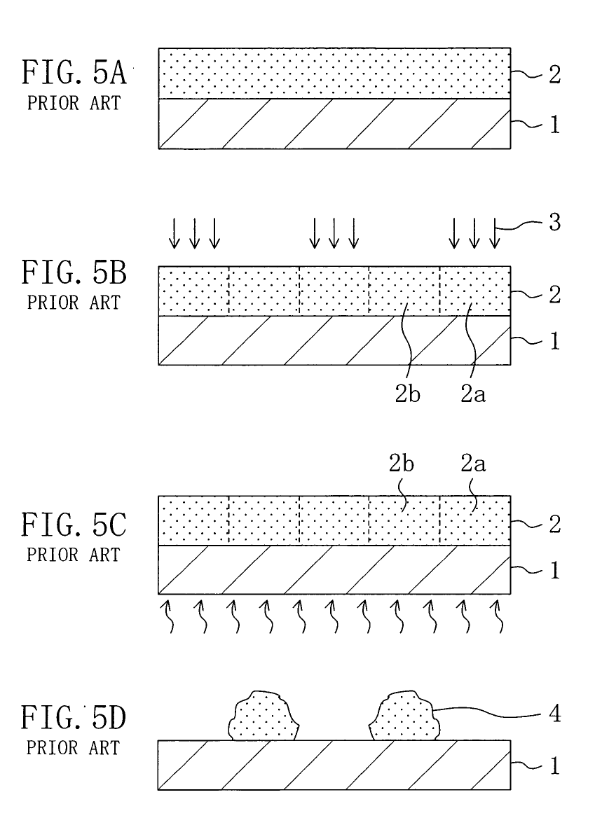

### DETAILED DESCRIPTION OF THE INVENTION

A pattern formation method according to each embodiment of the invention will now be described. It is noted that a substance simply designated as a “polymer” herein means a “polymer whose solubility in a developer is changed owing to a function of an acid”.

### EMBODIMENT 1

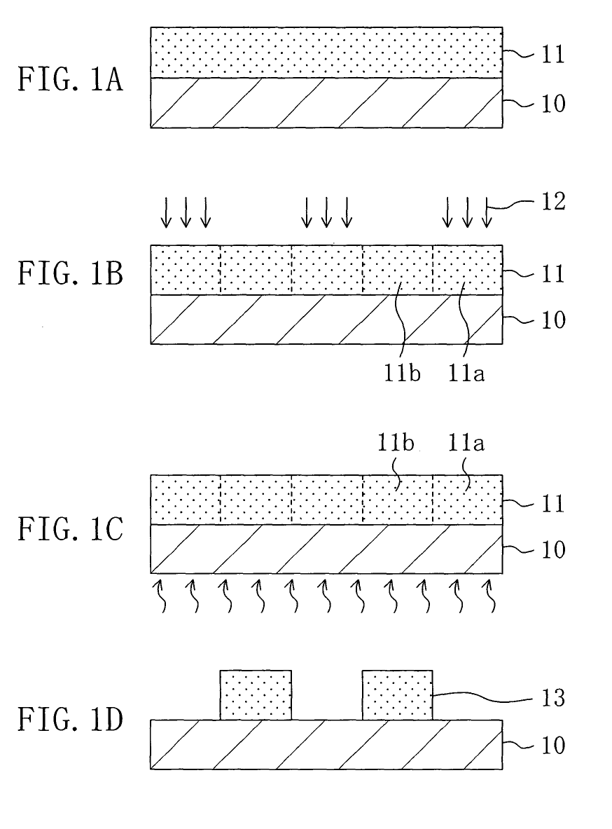

A pattern formation method according to Embodiment 1 of the invention will now be described with reference to FIGS. 1A through 1D.

First, a chemically amplified resist material having the following composition is prepared:

Polymer: poly((t-butyl methacrylate)—(mevalonic lactone methacrylate))

(wherein t-butyl methacrylate : mevalonic lactone methacrylate=50 mol %: 50 mol %). . . 2 g

Acid generator: triphenylsulfonium triflate . . . 0.08 g

Crushed carbon: particulate Shirasagi G2c (trade mark; manufactured by Takeda Chemical Industries, Ltd.) . . . 0.16 g

Solvent: propylene glycol monomethyl ether acetate . . . 20 g

Next, as shown in FIG. 1A, the aforementioned chemically amplified resist material is applied on a semiconductor substrate 10 by spin coating, so as to form a resist film 11 with a thickness of 0.2 μm.

Then, as shown in FIG. 1B in, pattern exposure is carried out by irradiating the resist film 11 with extreme UV 12 of a wavelength of 13.5 nm through a reflection mask not shown.

Thereafter, as shown in FIG. 1C, the resist film 11 is subjected to post-bake with a hot plate at a temperature of 100° C. for 60 seconds. Thus, an exposed portion 11a of the resist film 11 becomes soluble in an alkaline developer owing to the function of an acid generated from the acid generator while an unexposed portion 11b of the resist film 11 remains to be insoluble in an alkaline developer because no acid is generated from the acid generator therein.

Subsequently, as shown in FIG. 1D, the resist film 11 is developed with a 2.38 wt % tetramethylammonium hydroxide developer (alkaline developer). Thus, a resist pattern 13 with a line width of 0.07 μm made of the unexposed portion 11b of the resist film 11 can be obtained.

In Embodiment 1, the chemically amplified resist material includes the crushed carbon as a compound for absorbing outgassing. Therefore, the outgassing induced from the resist film 11 through the irradiation with the extreme UV 12 is absorbed by the crushed carbon and is minimally released in the exposure system, and hence, the outgassing minimally adheres onto a mirror or a mask of the exposure system.

As a result, degradation of the shape of the resist pattern 13 and lowering of the throughput can be avoided.

### EMBODIMENT 2

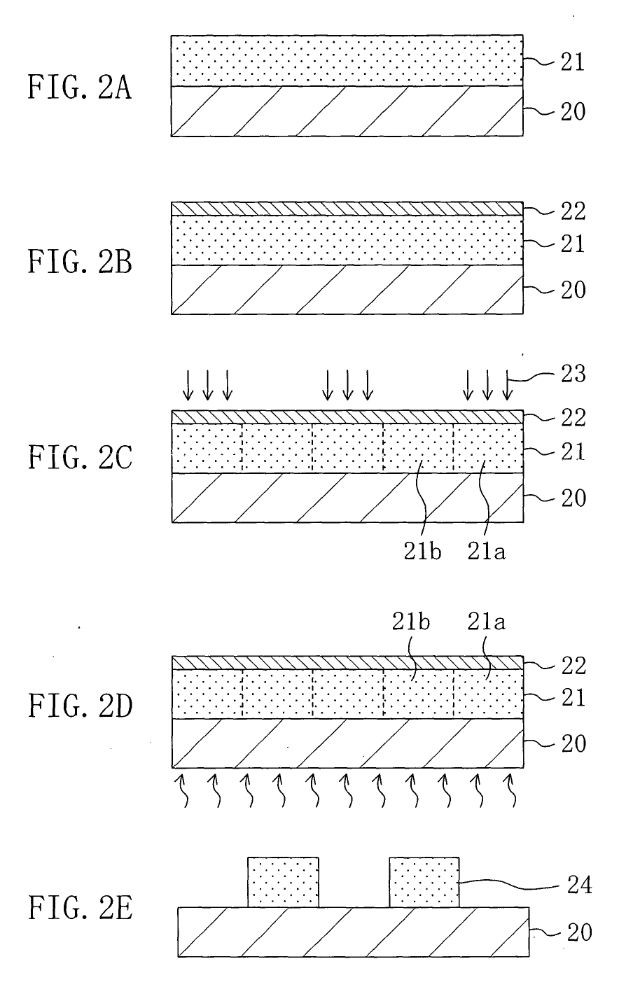

A pattern formation method according to Embodiment 2 of the invention will now be described with reference to FIGS. 2A through 2E.

First, a chemically amplified resist material having the following composition is prepared:

Polymer: poly((t-butyl methacrylate)—(mevalonic lactone methacrylate))

(wherein t-butyl methacrylate: mevalonic lactone methacrylate=50 mol %: 50 mol %) . . . 2 g

Acid generator: triphenylsulfonium triflate . . . 0.08 g

Solvent: propylene glycol monomethyl ether acetate . . . 20 g

Next, as shown in FIG. 2A, the aforementioned chemically amplified resist material is applied on a semiconductor substrate 20 by the spin coating, so as to form a resist film 21 with a thickness of 0.2 μm.

Then, as shown in FIG. 2B, a water-soluble material having the following composition is applied on the resist film 21 by the spin coating, so as to form a water-soluble film 22 with a thickness of 0.05 μm:

Water-soluble polymer: polyvinyl pyrrolidone . . . 0.6 g

Particulate carbon: spherical Shirasagi LGK-700 (trade mark; manufactured by Takeda Chemical Industries, Ltd.) . . . 0.16 g

Water . . . 20 g

Next, as shown in FIG. 2C, pattern exposure is carried out by irradiating the water-soluble film 22 and the resist film 21 with extreme UV 23 of a wavelength of 13.5 nm through a reflection mask not shown.

Then, as shown in FIG. 2D, the resist film 21 is subjected to the post-bake with a hot plate at a temperature of 100° C. for 60 seconds. Thus, an exposed portion 21a of the resist film 21 becomes soluble in an alkaline developer owing to the function of an acid generated from the acid generator while an unexposed portion 21b of the resist film 21 remains to be insoluble in an alkaline developer because no acid is generated from the acid generator therein.

Thereafter, as shown in FIG. 2E, a 2.38 wt % tetramethylammonium hydroxide developer (alkaline developer) is supplied onto the water-soluble film 22 and the resist film 21, so as to remove the water-soluble film 22 and to form a resist pattern 24 with a line width of 0.07 μm made of the unexposed portion 21b of the resist film 21.

In Embodiment 2, since the water-soluble film 22 includes the particulate carbon as a compound for absorbing outgassing, outgassing induced from the resist film 21 through the irradiation with the extreme UV 23 is absorbed by the particulate carbon and is minimally released in the exposure system. Therefore, the outgassing minimally adheres onto a mirror or a mask of the exposure system.

As a result, the degradation of the shape of the resist pattern 24 and the lowering of the throughput can be avoided.

### EMBODIMENT 3

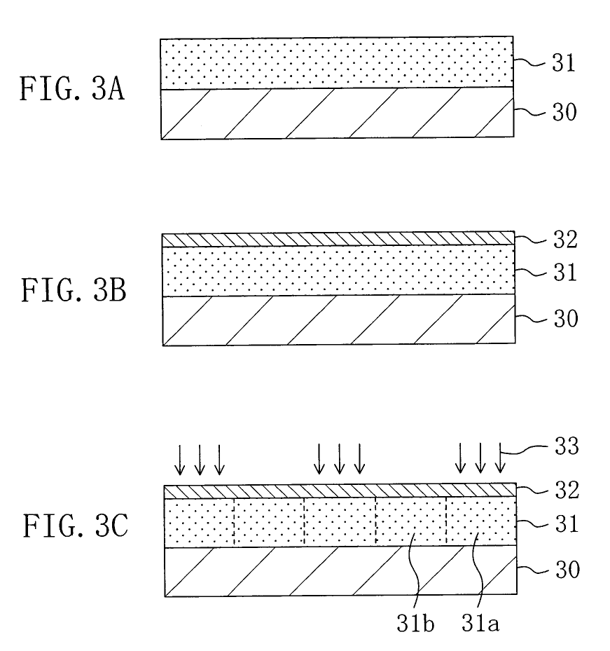

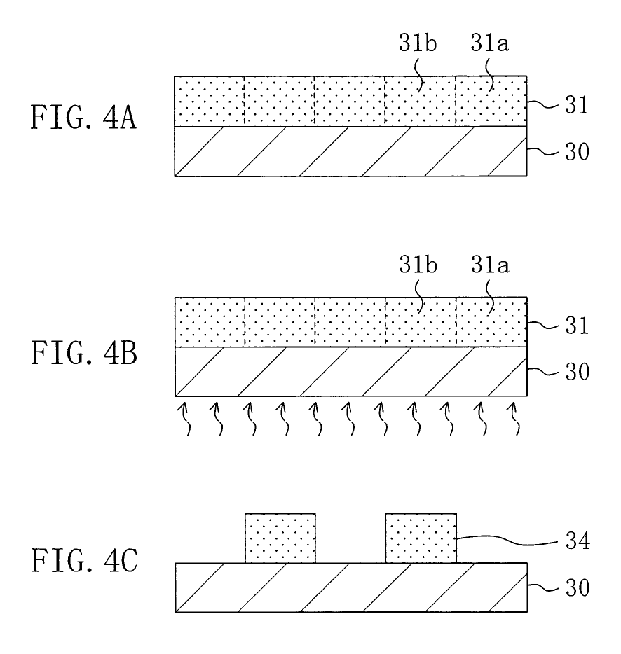

A pattern formation method according to Embodiment 3 of the invention will now be described with reference to FIGS. 3A through 3C and 4A through 4C.

First, a chemically amplified resist material having the following composition is prepared:

Polymer: poly((t-butyl methacrylate)—(mevalonic lactone methacrylate))

(wherein t-butyl methacrylate : mevalonic lactone methacrylate=50 mol %:50 mol % . . . 2 g

Acid generator: triphenylsulfonium triflate . . . 0.08 g

Solvent: propylene glycol monomethyl ether acetate . . . 20 g

Next, as shown in FIG. 3A, the aforementioned chemically amplified resist material is applied on a semiconductor substrate 30 by the spin coating, so as to form a resist film 31 with a thickness of 0.2 μm.

Then, as shown in FIG. 3B, a water-soluble material having the following composition is applied on the resist film 31 by the spin coating, so as to form a water-soluble film 32 with a thickness of 0.05 μm:

Water-soluble polymer: polyvinyl pyrrolidone . . . 0.6 g

Particulate carbon: spherical Shirasagi LGK-700 (trade mark; manufactured by Takeda Chemical Industries, Ltd.) . . . 0.16 g

Water . . . 20 g

Next, as shown in FIG. 3C, pattern exposure is carried out by irradiating the water-soluble film 32 and the resist film 31 with extreme UV 33 of a wavelength of 13.5 nm through a reflection mask not shown.

Thereafter, as shown in FIG. 4A, the water-soluble film 32 is removed by washing with a rinse.

Then, as shown in FIG. 4B, the resist film 31 is subjected to the post-bake with a hot plate at a temperature of 100° C. for 60 seconds. Thus, an exposed portion 31a of the resist film 31 becomes soluble in an alkaline developer owing to the function of an acid generated from the acid generator while an unexposed portion 31b of the resist film 31 remains to be insoluble in an alkaline developer because no acid is generated from the acid generator therein.

Next, as shown in FIG. 4C, the resist film 31 is developed with a 2.38 wt % tetramethylammonium hydroxide developer (alkaline developer). Thus, a resist pattern 34 with a line width of 0.07 μm made of the unexposed portion 31b of the resist film 31 is obtained.

In Embodiment 3, since the water-soluble film 32 includes the particulate carbon as a compound for absorbing outgassing, outgassing induced from the resist film 31 through irradiation with the extreme UV 33 is absorbed by the particulate carbon and is minimally released in the exposure system. Therefore, the outgassing minimally adheres onto a mirror or a mask of the exposure system.

As a result, the degradation of the shape of the resist pattern 34 and the lowering of the throughput can be avoided.

Although activated carbon working as the compound for absorbing outgassing is the crushed carbon in Embodiment 1 and particulate carbon in Embodiments 2 and 3, the activated carbon is not limited those described in these embodiments. Any particulate activated carbon made of crushed carbon, granular carbon, mold carbon (cylindrical carbon) or particulate carbon, or any activated carbon other than the particulate activated carbon may be used as the compound for absorbing outgassing.

In Embodiment 1, the weight ratio of the activated carbon to the polymer is 8%, which does not limit the invention. In each of Embodiments 2 and 3, the weight ratio of the activated carbon to the polymer is 26.7%, which does not limit the invention. Outgassing induced from a resist film can be efficiently absorbed as far as the weight ratio of the activated carbon is not less than 0.1% and not more than 30%.

Although extreme UV is used as the exposing light in each of Embodiments 1 through 3, the exposing light may be any energy beam such as F₂ laser or an electron beam instead.

What is claimed is:

1. A pattern formation material comprising a chemically amplified resist material including:
a polymer whose solubility in a developer is changed owing to a function of an acid;
an acid generator that generates an acid through irradiation with an energy beam; and
a compound that absorbs outgassing induced from said polymer or said acid generator.

2. The pattern formation material of claim 1,
wherein said compound is activated carbon.

3. The pattern formation material of claim 2,
wherein a weight ratio of said activated carbon to said polymer is not less than 0.1% and not more than 30%.

4. The pattern formation material of claim 2,
wherein said activated carbon is particulate activated carbon.

5. The pattern formation material of claim 4,
wherein said particulate activated carbon is crushed carbon, granular carbon, mold carbon (cylindrical carbon) or particulate carbon.

6. A water-soluble material for use for forming a water-soluble film on a resist film that is made from a chemically amplified resist material including a polymer whose solubility in a developer is changed owing to a function of an acid and an acid generator that generates an acid through irradiation with an energy beam, comprising:
a water-soluble polymer; and
a compound that absorbs outgassing induced from said resist film.

7. The water-soluble material of claim 6,
wherein said water-soluble polymer is one or two polymers selected from the group consisting of polyacrylic acid, polystyrene sulfonic acid, hydroxyethylcellulose, polyisoprene sulfonic acid, polyvinyl pyrrolidone and pullulan.

8. The water-soluble material of claim 6,
wherein said compound is activated carbon.

9. The water-soluble material of claim 8,
wherein said activated carbon is particulate activated carbon.

10. The water-soluble material of claim 9,
wherein said particulate activated carbon is crushed carbon, granular carbon, mold carbon (cylindrical carbon) or particulate carbon.

11. A pattern formation method comprising the steps of:
forming a resist film made from a chemically amplified resist material including a polymer whose solubility in a developer is changed owing to a function of an acid, an acid generator that generates an acid through irradiation with an energy beam and a compound that absorbs outgassing induced from said polymer or said acid generator;
performing pattern exposure by selectively irradiating said resist film with an energy beam; and
forming a resist pattern by developing said resist film with a developer after the pattern exposure.

12. The pattern formation method of claim 11,
wherein said energy beam is F₂ laser, extreme UV or an electron beam.

13. The pattern formation method of claim 11,
wherein said compound is activated carbon.

14. The pattern formation method of claim 13,
wherein a weight ratio of said activated carbon to said polymer is not less than 0.1% and not more than 30%.

15. The pattern formation method of claim 13,
wherein said activated carbon is particulate activated carbon.

16. The pattern formation method of claim 15,
wherein said particulate activated carbon is crushed carbon, granular carbon, mold carbon (cylindrical carbon) or particulate carbon.

17. A pattern formation method comprising the steps of:
forming a resist film made from a chemically amplified resist material including a polymer whose solubility in a developer is changed owing to a function of an acid and an acid generator that generates an acid through irradiation with an energy beam;
forming, on said resist film, a water-soluble film made from a water-soluble material including a water-soluble polymer and a compound that absorbs outgassing induced from said resist film;
performing pattern exposure by selectively irradiating said water-soluble film and said resist film with an energy beam; and
removing said water-soluble film and forming a resist pattern made from said resist film by developing said water-soluble film and said resist film with a developer after the pattern exposure.

18. The pattern formation method of claim 17,
wherein said water-soluble polymer is one or two polymers selected from the group consisting of polyacrylic acid, polystyrene sulfonic acid, hydroxyethylcellulose, polyisoprene sulfonic acid, polyvinyl pyrrolidone and pullulan.

19. The pattern formation method of claim 17,
wherein said energy beam is F₂ laser, extreme UV or an electron beam.

20. The pattern formation method of claim 17,
wherein said compound is activated carbon.

21. The pattern formation method of claim 20,
wherein a weight ratio of said activated carbon to said polymer is not less than 0.1% and not more than 30%.

22. The pattern formation method of claim 20,
wherein said activated carbon is particulate activated carbon.

23. The pattern formation method of claim 22,
wherein said particulate activated carbon is crushed carbon, granular carbon, mold carbon (cylindrical carbon) or particulate carbon.

24. A pattern formation method comprising the steps of:
forming a resist film made from a chemically amplified resist material including a polymer whose solubility in a developer is changed owing to a function of an acid and an acid generator that generates an acid through irradiation with an energy beam;
forming, on said resist film, a water-soluble film made from a water-soluble material including a water-soluble polymer and a compound that absorbs outgassing induced from said resist film;
performing pattern exposure by selectively irradiating said water-soluble film and said resist film with an energy beam;
removing said water-soluble film after the pattern exposure; and
forming a resist pattern by developing said resist film with a developer after the pattern exposure.

25. The pattern formation method of claim 24,
wherein said water-soluble polymer is one or two polymers selected from the group consisting of polyacrylic acid, polystyrene sulfonic acid, hydroxyethylcellulose, polyisoprene sulfonic acid, polyvinyl pyrrolidone and pullulan.

26. The pattern formation method of claim 24,
wherein said energy beam is F₂ laser, extreme UV or an electron beam.

27. The pattern formation method of claim 24,
wherein said compound is activated carbon.

28. The pattern formation method of claim 27,
wherein a weight ratio of said activated carbon to said polymer is not less than 0.1% and not more than 30%.

29. The pattern formation method of claim 27,
wherein said activated carbon is particulate activated carbon.

30. The pattern formation method of claim 29,
wherein said particulate activated carbon is crushed carbon, granular carbon, mold carbon (cylindrical carbon) or particulate carbon.
